(19) United States
(12) Patent Application Publication
(10) Pub. No.: US 2012/0104482 A1
(43) Pub. Date: May 3, 2012

(54) SEMICONDUCTOR DEVICES HAVING A CONTROL GATE ELECTRODE INCLUDING A METAL LAYER FILLING A GAP BETWEEN ADJACENT FLOATING GATES AND METHODS OF FABRICATING THE SAME

(75) Inventors: Hong-Suk KIM, Yongin-si (KR); Jun Kyu AHN, Seoul (KR); Jae Young AHN, Seongnam-si (KR); Ki Hyun HWANG, Seongnam-si (KR); Yong Hyun KWON, Hwaseong-si (KR)

(73) Assignee: SAMSUNG ELECTRONICS CO., LTD., Suwon-si (KR)

(21) Appl. No.: 13/241,387

(22) Filed: Sep. 23, 2011

(30) Foreign Application Priority Data
Nov. 3, 2010 (KR) 10-2010-0108825

(51) Int. Cl. H01L 29/788

(52) U.S. Cl. 257/316; 257/E29.3

(57) ABSTRACT

A semiconductor device includes a device isolation layer defining a plurality of active regions of a semiconductor substrate, floating gates and a control gate electrode in which the lowermost part of the electrode is constituted by a metal layer. The control gate electrode crosses over the active regions. The floating gates are disposed between the control gate electrode and the active regions. The tops of the floating gates are disposed at a level above the level of the top of the device isolation layer such that a gap is defined between adjacent ones of the floating gates. A region of the gap is filled with the metal layer of the control gate electrode.

### PRIORITY STATEMENT

This U.S. non-provisional patent application claims priority under 35 U.S.C. §119 of Korean Patent Application No. 10-2010-0108825, filed on Nov. 3, 2010, the entire contents of which are hereby incorporated by reference.

### BACKGROUND

The inventive concept relates to semiconductor devices and to methods of fabricating the same. More particularly, the inventive concept relates to semiconductor devices having a control gate electrode and floating gates, and to methods of fabricating the same.

Semiconductor devices may be classified as memory devices, non-memory devices or embedded memory. Memory devices and embedded memory devices include a plurality of memory cells. The memory cells may be nonvolatile memory cells and/or volatile memory cells.

A flash memory device is a nonvolatile memory device having a plurality of nonvolatile memory cells. Each nonvolatile memory cell, or unit cell, of a flash memory device may include a floating gate and a control gate electrode which are stacked on an active region. As flash memory devices become more highly integrated, the distance between the unit cells is becoming smaller and smaller. As a result, highly integrated flash memory devices may have several problems. For example, in a highly integrated flash memory device, a gap between floating gates formed on a pair of adjacent active regions is relatively narrow. In this case, a void may be present in a polysilicon layer constituting a lowermost layer of the control gate electrode adjacent to the floating gates. The void is formed as the polysilicon layer fills the gap, during the process of forming the control gate electrode, due to the narrowness of the gap. Such void, when formed, decreases the coupling ratio of the flash memory cells, thereby degrading a program characteristic and an erase characteristic of the memory device.

Additionally, when the polysilicon layer of the control gate electrode is doped with N-type impurities and a positive bias is applied to the control gate electrode, a depletion layer may be formed in a bottom portion of the polysilicon layer constituting the control gate electrode. If the gap is too narrow, the portion of the polysilicon layer occupying the gap may be fully depleted. As a result, the polysilicon layer in the gap may prevent the control gate electrode from performing properly, i.e., may reduce the coupling ratio.

Furthermore, it is difficult to formulate a solution to the problem of leakage current, with respect to an inter-gate insulating layer between the floating gate and the control gate electrode, when the control gate electrode has a lowermost layer of polysilicon as mentioned above. Thus, there is a limit to how low the threshold voltage of erased memory cells in a flash memory device can be when the lowermost layer of the control gate electrode is formed of polysilicon. That is, relatively high operation voltages of flash memory devices having multi-bit cells must be used when the control gate electrode has a lowermost layer of polysilicon.

### SUMMARY

According to one aspect of the inventive concept, there is provided a semiconductor device comprising: a semiconductor substrate, a device isolation layer disposed at a region of the semiconductor substrate and demarcating a plurality of active regions of the semiconductor substrate, a control gate electrode crossing over the active regions and in which a lowermost layer of the control gate electrode is constituted by a metal layer, and floating gates disposed between the control gate electrode and the active regions. The floating gates have top surfaces, respectively, disposed at a level above the level of the top surface of the device isolation layer such that a gap on the device isolation layer is defined by and between adjacent ones of the floating gates, and the lowermost layer of the control gate electrode fills a region of the gap.

According to another aspect of the inventive concept, there is provided a method of fabricating a semiconductor device, comprising: forming a device isolation layer at an upper portion of a semiconductor substrate to demarcate active regions of the substrate, forming floating gate patterns on the active regions in such a way that top surfaces of the floating gate patterns are disposed at a level above the level of the top surface of the device isolation layer and a gap is defined between adjacent ones of the floating gate patterns on the device isolation layer, and subsequently forming a control gate electrode on the semiconductor substrate, wherein the forming of the control gate electrode comprises forming a lowermost layer filling a region of the gap with metallic material.

According to another aspect of the inventive concept, there is provided a method of fabricating a semiconductor device, comprising: forming a device isolation layer at an upper portion of a semiconductor substrate to demarcate active regions of the semiconductor substrate, forming floating gate patterns on the active regions as spaced apart from one another and such that gaps are defined each on the device isolation layer by and between adjacent ones of a respective pair of the floating gate patterns, forming an interlayer insulator over the floating gate patterns such that a portion of each of the gaps remain between the floating gate patterns, and forming a control gate electrode on the semiconductor substrate across the active regions, wherein the forming of the control gate electrode comprises forming metallic material on the semiconductor substrate, to such a thickness as to fill the portions of the gaps with the metallic material, and the filling of the portions of the gaps with metallic material forms the lowermost part of the control gate electrode.

### BRIEF DESCRIPTION OF THE DRAWINGS

These and other aspects of the inventive concept will become more clearly understood from the following detailed description of the preferred embodiments thereof made with reference to the accompanying drawings. In the figures:

FIG. 1 is a plan view of flash memory cells of a semiconductor device according to the inventive concept;

FIGS. 2 and 3 are sectional views taken along lines I-I′ and II-IF of FIG. 1, respectively;

FIGS. 4 through 9 are sectional views, each taken in the direction of line I-I′ of FIG. 1, and together illustrate a method of fabricating a semiconductor device according to the inventive concept; and

FIG. 10 is an energy band diagram illustrating positive and negative leakage current characteristics of an inter-gate insulating layer of a flash memory cell of a semiconductor device according to the inventive concept.

### DETAILED DESCRIPTION OF THE PREFERRED EMBODIMENTS

Various embodiments and examples of embodiments of the inventive concept will be described more fully hereinafter with reference to the accompanying drawings. In the drawings, the sizes and relative sizes and shapes of elements, layers and regions, such as implanted regions, shown in section may be exaggerated for clarity. In particular, the cross-sectional illustrations of the semiconductor devices and intermediate structures fabricated during the course of their manufacture are schematic. Also, like numerals are used to designate like elements throughout the drawings.

Other terminology used herein for the purpose of describing particular examples or embodiments of the inventive concept is to be taken in context. For example, the terms “comprises” or “comprising” when used in this specification specifies the presence of stated features or processes but does not preclude the presence or additional features or processes.

Furthermore, spatially relative terms, such as “upper,” and “lower” are used to describe an element's and/or feature's relationship to another element(s) and/or feature(s) as illustrated in the figures. Thus, the spatially relative terms may apply to orientations in use which differ from the orientation depicted in the figures. Obviously, though, all such spatially relative terms refer to the orientation shown in the drawings for ease of description and are not necessarily limiting as embodiments according to the inventive concept can assume orientations different than those illustrated in the drawings when in use. In addition, the terms “upper” or “bottom” as used to describe a surface generally refer not only to the orientation depicted in the drawings but to the fact that the surface is the uppermost or bottommost surface in the orientation depicted, as would be clear from the drawings and context of the written description.

It will also be understood that when an element or layer is referred to as being “on” or “adjacent to” another element or layer, it can be directly on or directly adjacent to the other element or layer or intervening elements or layers may be present. In contrast, when an element or layer is referred to as being “directly on” or “directly adjacent to” another element or layer, there are no intervening elements or layers present.

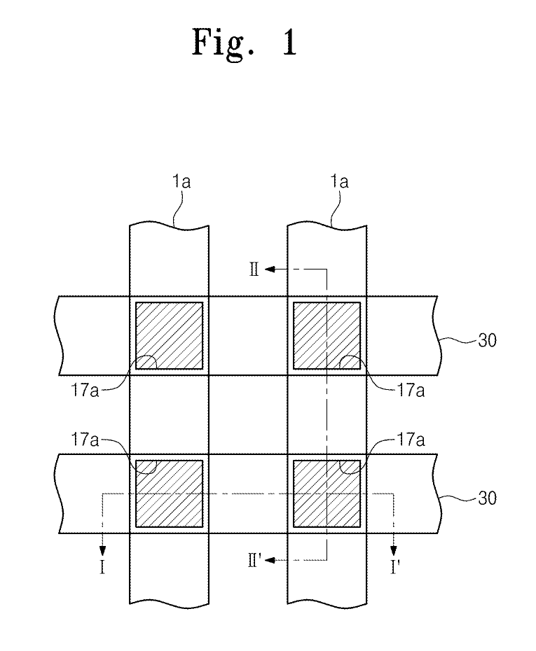

An embodiment of a semiconductor device according to the inventive concept will now be described with reference to FIGS. 1 through 3.

The semiconductor device includes a substrate 1, a device isolation layer 11a disposed at a predetermined region of a semiconductor substrate 1 to define a plurality of active regions 1a, control gate electrodes 30 crossing over the active regions 1a, and floating gates 17a disposed at intersections of the control gate electrodes 30 and the active regions 1a, respectively. In particular, each floating gate 17a is disposed between a control gate electrode 30 and an active region 1a. The respective floating gates 17a may comprise a silicon layer, and the respective control gate electrodes 30 each comprise a metal pattern 25b constituting at least the lowermost layer of the electrode.

Also, in this embodiment, a tunnel insulating layer 15 is interposed between the floating gates 17a and the active regions 1a, and an inter-gate insulator 24 is interposed between the floating gates 17a and the control gate electrodes 30. The inter-gate insulator 24 may include a lower inter-gate insulating layer 21, and an upper inter-gate insulating layer 24 stacked on the lower inter-gate insulating layer 21. Thus, in this case, the lower inter-gate insulating layer 21 is adjacent to the floating gates 17a, and the upper inter-gate insulating layer 23 is adjacent to the control gate electrodes 30. In particular, the upper inter-gate insulating layer 23 is directly adjacent to, i.e., is in contact with, the metal patterns 25b constituting at least the lowermost layers of the control gate electrodes 30.

As examples of this embodiment of the inventive concept, the lower inter-gate insulating layer 21 may be an oxide layer, a combination of an oxide layer and a nitride layer (an ON layer), or a combination of an oxide layer, a nitride layer and an oxide layer (an ONO layer); and the upper inter-gate insulating layer 23 may be a high-k dielectric layer which has a dielectric constant higher than that of the lower inter-gate insulating layer 21. In this specification, a high-k dielectric layer will refer to a dielectric layer having a dielectric constant higher than that of a silicon nitride layer.

Although the upper inter-gate insulating layer 23 is in direct contact with a lowermost metal pattern 25b, the upper inter-gate insulating layer 23 does not chemically react with the lowermost metal pattern 25b because it is of a stable high-k dielectric layer. For example, when the lowermost metal pattern 25b is a metal layer comprising titanium or tantalum, the upper inter-gate insulating layer 23 may comprise any of an aluminum oxide layer, a hafnium oxide layer, a hafnium silicate layer, a zirconium oxide layer and a zirconium silicate layer.

The lowermost metal pattern 25b comprises a metal layer having an excellent characteristic for filling narrow and deep spaces, i.e., may comprise a metal layer that is not prone to having voids form therein when the material thereof is deposited in a gap or other type of opening having a high aspect ratio. In examples of this embodiment, the lowermost metal pattern 25b may include a titanium nitride layer or a tantalum nitride layer.

Each of the control gate electrodes 30 may further include an upper metal layer, having low electrical resistance, disposed on the lowermost metal pattern 25b. That is, the resistivity of the upper metal layer may be lower than that of the lowermost metal pattern 25b. Such an upper metal layer may include a first upper metal pattern 27a, and a second upper metal pattern 29a stacked on the first upper metal pattern 27a. In an example of this embodiment, the first upper metal pattern 27a and the second upper metal pattern 29a are a tungsten nitride pattern and a tungsten pattern, respectively. In another example, the first upper metal pattern 27a and the second upper metal pattern 29a are a tungsten silicide pattern and a tungsten pattern, respectively. In still another example, the first and second upper metal patterns 27a and 29a may be a tungsten nitride pattern and a tungsten pattern, respectively, and a tungsten silicide pattern is interposed between the first and the second metal patterns 27a and 29a.

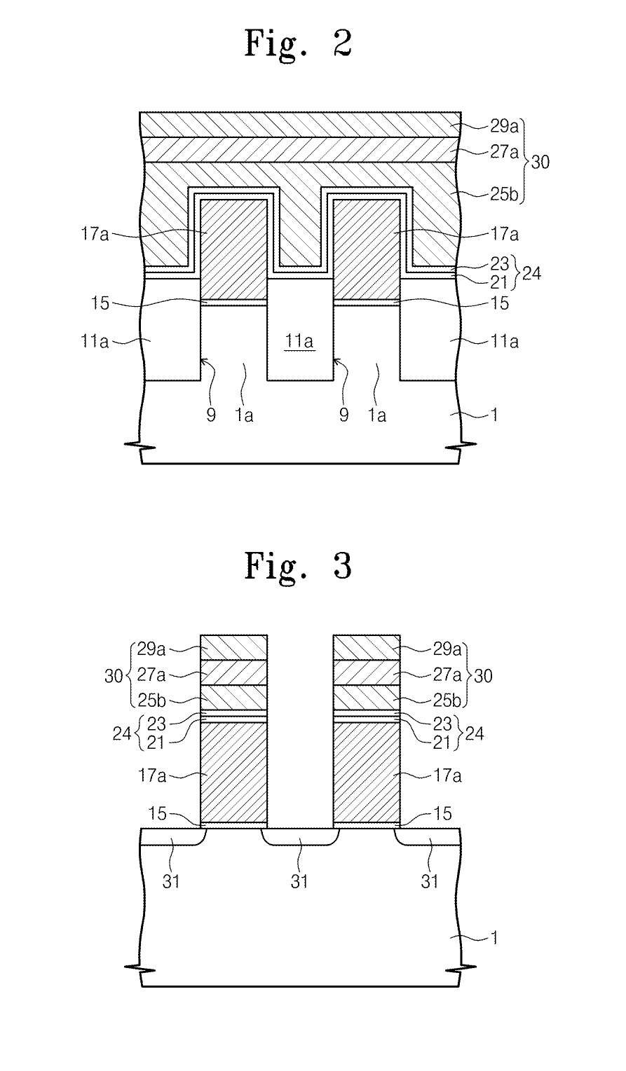

Referring still to FIGS. 2 and 3, each floating gate 17a has a top surface disposed at a level above the device isolation layer 11a. Therefore, gaps are defined by and between the floating gates 17a. In particular, each gap is located on the device isolation layer 11a between adjacent ones of the floating gates 17a. The gaps are filled by the lowermost metal patterns 25b. Also, in this embodiment, the lowermost metal pattern 25b has a work function higher than that of the floating gates 17a. Thus, even if a program voltage, i.e., a positive voltage, is applied to the control gate electrodes 30, depletion layers are not formed in the control gate electrodes 30. As a result, a flash memory cell according to the inventive concept has a stable coupling ratio.

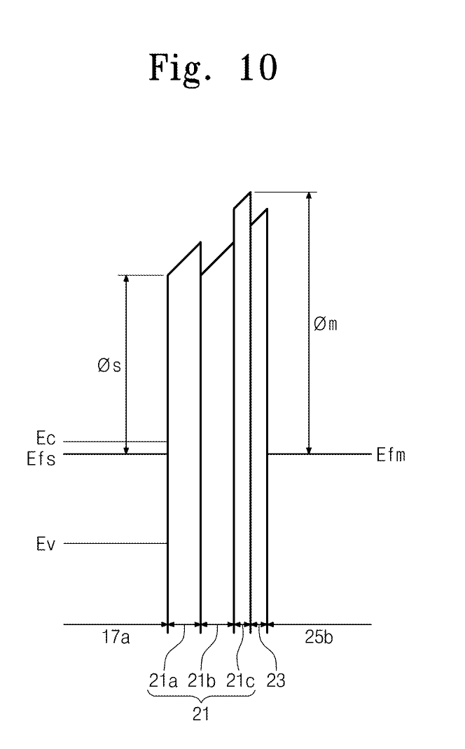

The leakage current characteristic of the inter-gate insulating layer of a flash memory device according to the inventive concept will be described with reference to FIG. 10.

FIG. 10 is an energy band diagram of a cell gate pattern of a flash memory device according to the inventive concept. In FIG. 10, reference symbols “Ec” and “Ev” represent a conduction band and a valence band, respectively. For the purpose of ease and convenience in explanation, it is assumed that the lower inter-gate insulating layer 21 described with reference to FIGS. 1 through 3 is an ONO layer including a lower silicon oxide layer 21a, a silicon nitride layer 21b and an upper silicon oxide layer 21c. In addition, the floating gate 17a is a polysilicon layer doped with N-type impurities.

Referring to FIG. 10, the lowermost metal pattern 25b has a work function Φₘ higher than a work function Φₛ of the floating gate 17a. As illustrated in FIG. 10, the Fermi level “Efm” of the lowermost metal pattern 25b has the same energy potential as the Fermi level “Efs” of the floating gate 17a in a thermal equilibrium state.

As described with reference to FIGS. 1 through 3, the upper inter-gate insulating layer 23 disposed between the lowermost metal pattern 25b and the lower inter-gate insulating layer 21 may be a dielectric layer which does not chemically react on the lowermost metal pattern 25b. Thus, the Fermi level “Efm” of the lowermost metal pattern 25b may be flat as shown in FIG. 10. That is, even if the upper inter-gate insulating layer 23 contacts the lowermost metal pattern 25b, the Fermi level at a surface of the lowermost metal pattern 25b adjacent to the upper inter-gate insulating layer 23 is equal to the Fermi level “Efm” of the bulk portion of the lowermost metal pattern 25b.

In an erasure operation mode when a voltage applied to the control gate electrode 30 is lower than that induced in the floating gate 17a, a barrier height of the inter-gate insulating layer 21+23 with respect to electrons in the control gate electrode 30 including the lowermost metal pattern 25b is equal to the work function Φₘ of the lowermost metal pattern 25b. Alternatively, in a program operation mode when a voltage applied to the control gate electrode 30 is higher than that induced in the floating gate 17a, the barrier height of the inter-gate insulating layer 21+23 with respect to electrons in the floating gate 17a is equal to the work function Φₛ of the floating gate 17a. Therefore, a negative leakage current characteristic of the inter-gate insulating layer 21+23 during the erasure operation is better than a positive leakage current characteristic of the inter-gate insulating layer 21+23 during the program operation.

In this case, in which the negative leakage current characteristic is better than the positive leakage current characteristic according to an aspect of the inventive concept, the absolute value of the erasure voltage can be increased. Thus, a memory device can be provided having a relatively large window between the threshold voltage of the erased memory cells and the threshold voltage of the programmed memory cells. Accordingly, each memory cell can store a large number of data bits. Furthermore, flash memory devices having multi-bit cells may be operated at a low voltage, according to the inventive concept, because the threshold voltage of the programmed memory cells can be kept to a minimum.

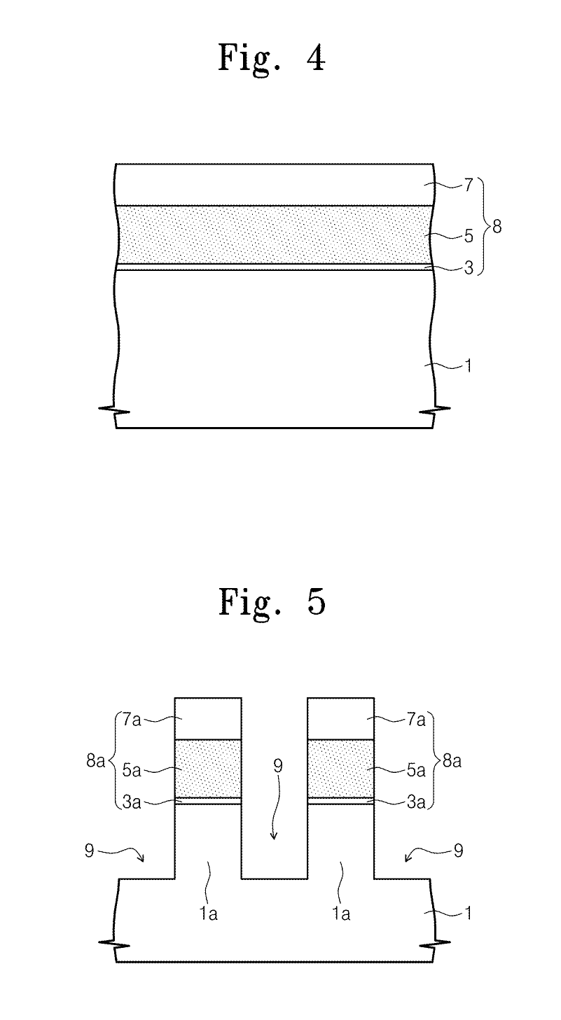

A method of fabricating a semiconductor device according to the inventive concept will now be described with reference to FIGS. 4 through 9.

Referring to FIG. 4, a trench mask 8 is formed on a semiconductor substrate 1. The trench mask 8 can be formed by sequentially stacking a buffer layer 3, a polishing stop layer 5 and a hard mask layer 7 on each other. The buffer layer 3 serves to alleviate a physical stress due to different rates of thermal expansion between the polishing stop layer 5 and the semiconductor substrate 1. In an example of this embodiment, the buffer layer 3 is a thermal oxide layer, and the polishing stop layer 5 is a silicon nitride layer. The hard mask layer 7 is preferably formed of an insulating layer having an etching selectivity with respect to the polishing stop layer 5 and the semiconductor substrate 1. For example, the hard mask layer 7 may be an oxide layer formed by chemical vapor deposition (CVD). The hard mask layer 7 is optional, however.

Referring to FIG. 5, the trench mask 8 is patterned to form a trench mask pattern 8a which exposes a predetermined region of the semiconductor substrate 1. As a result, the trench mask pattern 8a includes a buffer pattern 3a, a polishing stop pattern 5a and a hard mask pattern 7a (in the case in which the hard mask layer 7 is formed). The exposed semiconductor substrate 1 is etched using the trench mask pattern 8a as an etching mask, thereby forming a trench 9 which defines a plurality of active regions 1a.

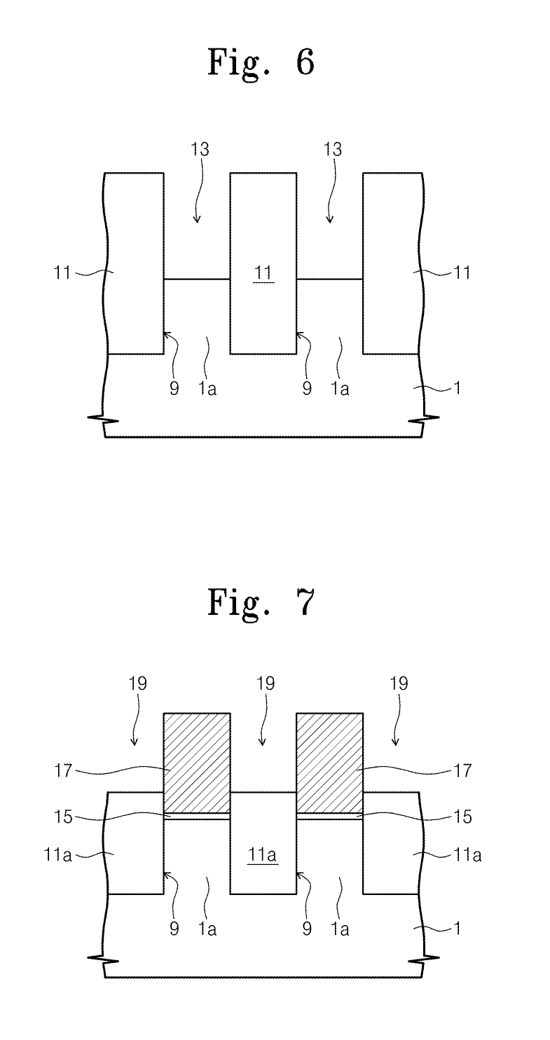

Referring to FIG. 6, a device isolation insulating layer is then formed over the entire surface of the semiconductor substrate to fill the trench 9. The device isolation insulating layer may be then planarized to expose the top surface of the trench mask pattern 8a and thereby form a device isolation insulating pattern 11 in the trench 9. During the planarization of the device isolation insulating layer, the hard mask patterns 7a may be removed (in the illustrated example) to expose the polishing stop patterns 5a. After the device isolation insulating pattern 11 is formed, the trench mask pattern 8a may be removed to form recesses 13 exposing the active regions 1a.

Referring to FIG. 7, a tunnel insulating layer 15 is formed on the exposed active regions 1a, and a conductive layer is formed on the substrate to fill (in particular, to overfill) the recesses 13. The conductive layer may be a semiconductor layer. In this example, the conductive layer is a doped polysilicon layer. For example, the conductive layer is an N-type polysilicon layer.

The conductive layer may be planarized to form floating gate patterns 17 in the grooves 13 and to expose the device isolation insulating pattern 11. The device isolation insulating pattern 11 is recessed to form a device isolation layer 11a whose top surface is disposed at a level lower than that of the top surfaces of the floating gate patterns 17. As a result, gaps 19 are formed on the device isolation layer 11a between the floating gate patterns 17.

As described above, in this example of a method of fabricating a semiconductor device according to the inventive concept, the floating gate patterns 17 are polysilicon patterns which are formed as self-aligned with the active regions 1a. That is, the floating gate patterns 17 are formed using a self-aligned polysilicon (SAP) technique. However, the inventive concept is not limited to the forming of the floating gate patterns 17 by a SAP technique. That is, other techniques may be used to form the floating gate patterns 17.

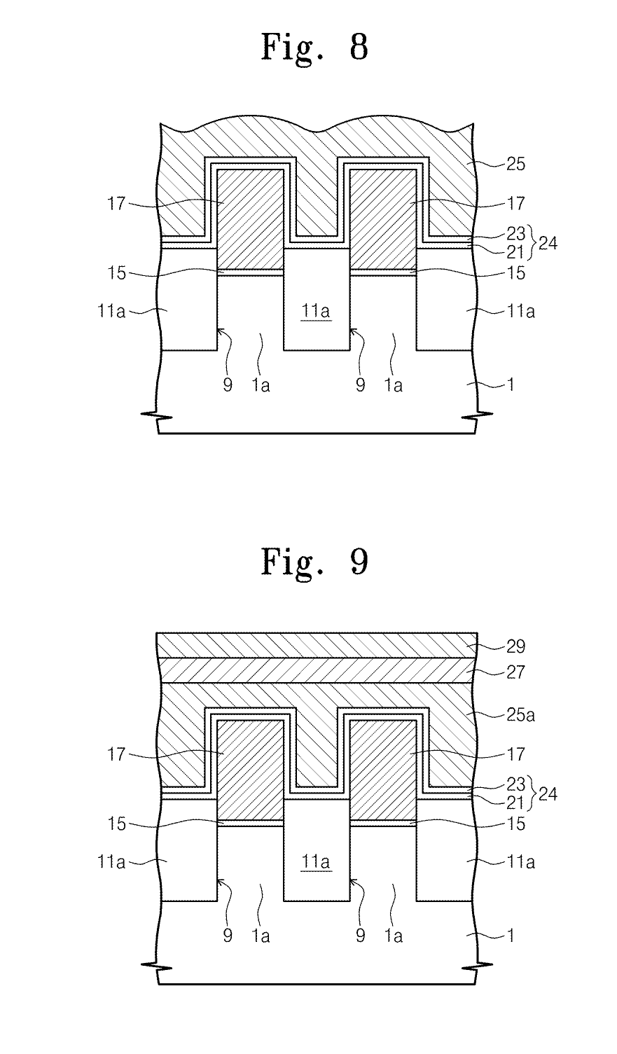

Referring to FIG. 8, an inter-gate insulator 24 is then conformally formed on the substrate. More specifically, the insulating material constituting the inter-gate insulator 24 is deposited to conform to the topography of the floating gate patterns 17, and to such a thickness as to leave portions of the gaps 19 between the floating gate patterns 17. The inter-gate insulator 24A may be formed by sequentially forming a lower inter-gate insulating layer 21 and then an upper inter-gate insulating layer 23. In an example of this embodiment, as was mentioned above, the lower inter-gate insulating layer 21 is formed of an oxide layer, a combination of an oxide layer and a nitride layer (an ON layer), or a combination of an oxide layer, a nitride layer and an oxide layer (an ONO layer). The upper inter-gate insulating layer 23 is formed of a high-k dielectric layer whose dielectric constant is higher than that of the lower inter-gate insulating layer 21. For example, the upper inter-gate insulating layer 23 is an aluminum oxide (AlO) layer, a hafnium oxide (HfO) layer, a hafnium silicate (HfSiO) layer, a zirconium oxide (ZrO) layer, a zirconium silicate (ZrSiO) layer or a composite layer of more than one film of such materials.

A first metal layer 25 is formed on the inter-gate insulating layer 24 to such a thickness as to fill (the remaining portions) of the gaps 19 between the floating gate patterns 17. These gaps 19 (or the remaining portions thereof) may be quite narrow especially in the case in which the semiconductor device being fabricated is a highly integrated device. Therefore, the first metal layer 25 is formed of conductive material having an excellent gap filling characteristic, i.e., which is capable of filling the gaps 19 without any voids. To this end, the first metal layer 25 may be formed of a titanium nitride layer or a tantalum nitride layer. Also, the first metal layer 25 may have a work function which is higher than that of the floating gate patterns 17.

In an example of this embodiment in which the first metal layer 25 is formed directly on the upper inter-gate insulating layer 23, the upper inter-gate insulating layer 23 is formed of a stable high-k dielectric layer which will not chemically react on the first metal layer 25. For example, the upper inter-gate insulating layer 23 is formed of a stable high-k dielectric layer which does not chemically react with a titanium nitride layer or a tantalum nitride layer. Otherwise, a metal oxide layer would be formed at an interface between the upper inter-gate insulating layer 23 and the first metal layer 25. In that case, the metal oxide layer between would lower the work function of the first metal layer 25 adjacent to the metal oxide layer, and the negative leakage current characteristic of the inter-gate insulating layer 24 would be degraded making it difficult to increase the erasure threshold voltage.

Referring to FIG. 9, second and third metal layers 27 and 29 are sequentially formed on the lowermost metal layer 25. Note, the lowermost metal layer 25 may be planarized, to form a planarized lowermost metal layer 25a, before the metal layers 27 and 29 are formed. In any case, the first through third metal layers 25 (25a), 27 and 29 make up a control gate conductor. The second and third metal layers 27 and 29 may be formed of tungsten nitride and tungsten, respectively. Alternatively, the second and third metal layers 27 and 29 may be formed of tungsten silicide and tungsten, respectively. In still another example, the second metal layer 27 is formed of tungsten nitride, a tungsten silicide is formed on the second metal layer 27, and then the third metal layer 29 is formed of tungsten on the tungsten silicide layer.

The control gate conductor 25a, 27 and 29, the inter-gate insulator 24 and the floating gate patterns 17 are then patterned to form control gate electrodes 30 crossing over the active regions 1a as well as floating gates 17a disposed at intersections of the control gate electrodes 30 and the active regions 1a, as illustrated in FIGS. 1, 2 and 3. Subsequently, impurities may be injected into the active regions 1a using the control gate electrodes 30 and the device isolation layer 11a as ion implantation masks, thereby forming source/drain regions (31 of FIG. 3).

As described above, according to the inventive concept, gaps between adjacent floating gates are filled with a metal layer which constitutes the lowermost part (bottom) of a control gate electrode. Thus, there will not be any voids in the portion of the control gate electrode that occupies the gaps. Accordingly, a depletion region will not be formed in the lowermost layer of the control gate electrode, regardless of the aspect ratio of the gaps. As a result, flash memory cells fabricated according to the inventive concept may have a high and relatively stable coupling ratio, and excellent program and erasure characteristics.

In addition, the lowermost part of the control gate electrode, which is constituted by a metal layer, may have a work function higher than that of the floating gates. In this case, it is possible to increase the potential barrier height of the inter-gate insulating layer with respect to electrons in the control gate electrode. As a result, flash memory cells may be provided in which the negative leakage current characteristic of the inter-gate insulating layer is improved. That is, the threshold voltage of erased memory cells can be relatively low while the threshold voltages of the programmed memory cells remains comparable to a device in which the lowermost layer of the control gate is of polysilicon. As a result, flash memory devices with multi-bit cells can be operated at a relatively low voltage.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A semiconductor device, comprising:
a semiconductor substrate;
a device isolation layer disposed at a region of the semiconductor substrate and demarcating a plurality of active regions of the semiconductor substrate;
a control gate electrode crossing over the active regions, a lowermost layer of the control gate electrode being constituted by a metal layer; and
floating gates disposed between the control gate electrode and the active regions,
wherein the floating gates have top surfaces, respectively, disposed at level above the level of the top surface of the device isolation layer such that a gap on the device isolation layer is defined by and between adjacent ones of the floating gates, and
the lowermost layer of the control gate electrode fills a region of the gap.

2. The semiconductor device of claim 1, wherein the lowermost layer of the control gate electrode has a work function higher than that of the floating gates.

3. The semiconductor device of claim 1, wherein the metal layer includes a titanium nitride layer or a tantalum nitride layer.

4. The semiconductor device of claim 1, wherein the control gate electrode further includes an upper metal layer stacked on the lowermost layer of the control gate electrode, and the upper metal layer has a resistivity lower than that of the lowermost layer.

5. The semiconductor device of claim 4, wherein the upper metal layer comprises at least one composite layer selected from the group consisting of a composite layer including tungsten nitride and tungsten stacked on the tungsten nitride, a composite layer including tungsten silicide and tungsten stacked on the tungsten silicide, and a composite layer including tungsten nitride, tungsten silicide stacked on the tungsten nitride and a tungsten stacked on the tungsten silicide.

6. The semiconductor device of claim 1, further comprising:
an inter-gate insulator interposed between the floating gates and the control gate electrode,
wherein the inter-gate insulator includes a lower inter-gate insulating layer adjacent to the floating gates and an upper inter-gate insulating layer adjacent to the control gate electrode.

7. The semiconductor device of claim 6, wherein the upper inter-gate insulating layer includes a high-k dielectric layer which does not chemically react on the lowermost metal layer.

8. The semiconductor device of claim 6, wherein the upper inter-gate insulating layer includes at least one of an aluminum oxide layer, a hafnium oxide layer, a hafnium silicate layer, a zirconium oxide layer and a zirconium silicate layer.

9. A method of fabricating a semiconductor device, comprising:
forming a device isolation layer at an upper portion of a semiconductor substrate to demarcate active regions of the substrate;
forming floating gate patterns on the active regions in such a way that top surfaces of the floating gate patterns are disposed at a level above the level of the top surface of the device isolation layer and a gap is defined between adjacent ones of the floating gate patterns on the device isolation layer; and
subsequently forming a control gate electrode on the semiconductor substrate,
wherein the forming of the control gate electrode comprises forming a lowermost layer filling a region of the gap with metallic material.

10. The method of claim 9, wherein the forming of the device isolation layer and the floating gate patterns comprises:
forming a trench mask pattern on the semiconductor substrate to expose a region of the semiconductor substrate;
etching the exposed region of the semiconductor substrate to form a trench which defines the active regions;
overfilling the trench with electrically insulating material to form the device isolation layer;
planarizing the device isolation layer until the trench mask pattern is exposed, thereby forming a device isolation insulating pattern which fills the trench;
removing the trench mask pattern to form recesses that expose the active regions;
forming floating gate patterns in the recesses, respectively; and
recessing the device isolation insulating pattern to form the device isolation layer whose top surface is disposed at a level beneath the level of the top surfaces of the floating gate patterns.

11. The method of claim 9, further comprising:
forming a tunnel insulating layer on the active regions before the floating gate patterns are formed such that the tunnel insulating layer becomes interposed between the active regions and the floating gate patterns.

12. The method of claim 9, further comprising:
forming an inter-gate insulator on the substrate after the floating gate patterns have been formed and before the control gate conductive layer is formed.

13. The method of claim 12, wherein the inter-gate insulator is formed by forming a lower inter-gate insulating layer, and forming an upper inter-gate insulating layer on the lower inter-gate insulating layer, wherein the lower inter-gate insulating layer has a dielectric constant lower than that of the upper inter-gate insulating layer.

14. The method of claim 9, wherein the lowermost layer has a work function which is higher than that of the floating gate patterns.

15. A method of fabricating a semiconductor device, comprising:
forming a device isolation layer at an upper portion of a semiconductor substrate to demarcate active regions of the semiconductor substrate;
forming floating gate patterns on the active regions as spaced apart from one another and such that gaps are defined each on the device isolation layer by and between adjacent ones of a respective pair of the floating gate patterns;
forming an interlayer insulator over the floating gate patterns such that a portion of each of the gaps remain between the floating gate patterns; and
forming a control gate electrode on the semiconductor substrate across the active regions,
wherein the forming of the control gate electrode comprises forming metallic material on the semiconductor substrate, while a portions of each gap remains between the adjacent ones of the floating gate patterns, to such a thickness as to fill the portions of the gaps with the metallic material, and
the filling of the portions of the gaps with metallic material forms the lowermost part of the control gate electrode.

16. The method of claim 15, wherein the forming of the device isolation layer and the floating gate patterns comprises:
forming a trench mask pattern on the semiconductor substrate to expose a region of the semiconductor substrate;
etching the exposed region of the semiconductor substrate to form a trench which defines the active regions;
overfilling the trench with electrically insulating material to form a device isolation layer;
planarizing the device isolation layer until the trench mask pattern is exposed, thereby forming a device isolation insulating pattern which fills the trench;
removing the trench mask pattern to form recesses that expose the active regions;
forming floating gate patterns in the recesses, respectively; and
recessing the device isolation insulating pattern to form the device isolation layer whose top surface is disposed at a level beneath the level of the top surfaces of the floating gate patterns.

17. The method of claim 15, further comprising:
forming a tunnel insulating layer on the active regions before the floating gate patterns are formed such that the tunnel insulating layer becomes interposed between the active regions and the floating gate patterns.

18. The method of claim 15, further comprising:
forming an inter-gate insulator on the semiconductor substrate after the floating gate patterns have been formed,
wherein the inter-gate insulator is formed by forming a lower inter-gate insulating layer, and forming an upper inter-gate insulating layer on the lower inter-gate insulating layer, wherein the lower inter-gate insulating layer has a dielectric constant lower than that of the upper inter-gate insulating layer.

19. The method of claim 15, wherein the lowermost part of the control gate electrode has a work function which is higher than that of the floating gate patterns.

20. The method of claim 15, wherein the forming of the control gate electrode further includes forming an upper metal layer on the metallic material constituting the lowermost part of the control gate electrode, the upper metal layer having a resistivity lower than that of the metallic material constituting the lowermost part of the control gate electrode.
